(19) United States
(12) Patent Application Publication
(10) Pub. No.: US 2026/0150708 A1
(43) Pub. Date: May 28, 2026

(54) SEMICONDUCTOR DEVICE AND METHOD OF MANUFACTURING THE SAME

(71) Applicant: Renesas Electronics Corporation, Tokyo (JP)

(72) Inventor: Koichi HASEGAWA, Tokyo (JP)

(21) Appl. No.: 19/342,783

(22) Filed: Sep. 29, 2025

(30) Foreign Application Priority Data
Nov. 26, 2024 (JP) 2024-205529

(51) Int. Cl. H01L 23/00; H01L 23/495; H01L 25/065

(52) U.S. Cl. CPC H10W 70/417; H10W 70/481; H10W 90/00; H10W 72/07631; H10W 72/865; H10W 72/868; H10W 72/871; H10W 72/884; H10W 72/886; H10W 72/926; H10W 72/932; H10W 72/936; H10W 72/9445; H10W 90/20; H10W 90/26; H10W 90/732; H10W 90/736; H10W 90/752; H10W 90/754; H10W 90/755; H10W 90/767

(57) ABSTRACT

A semiconductor device has a die pad, a semiconductor chip mounted on the die pad via a conductive material, and a lead terminal electrically connected to a source electrode of the semiconductor chip via a bonding member. Here, the source electrode includes a detection point for detecting a value of a current flowing in a power transistor provided in the semiconductor chip, and a bonding portion to which the bonding member is bonded. Then, a sense transistor provided in the semiconductor chip, the detection point, and the bonding portion do not overlap with a first region of the die pad, but overlap with a second region of the die pad. In addition, a thickness of the conductive material provided in the second region is larger than a thickness of the conductive material provided in the first region.

### CROSS-REFERENCE TO RELATED APPLICATIONS

The present application claims priority from Japanese Patent Application No. 2024-205529 filed on Nov. 26, 2024, the content of which is hereby incorporated by reference to this application.

### BACKGROUND

The present invention relates to a semiconductor device and a method of manufacturing the same.

A semiconductor device, in which a power semiconductor chip having a power transistor and a control semiconductor chip having a control circuit for controlling a gate potential of the power transistor are sealed, has been known. In addition, the control semiconductor chip may have a function of detecting a value of a load current of the power transistor. To detect the value of the load current, the power semiconductor chip is provided with a sense transistor for current sense beside the power transistor used as a main cell, and a part of a source electrode of the power transistor is provided with a detection point for detecting the value of the current. In a sense circuit included in the control semiconductor chip, the value of the current flowing in the power transistor is measured based on a value of a current flowing in the sense transistor and on a preset sense ratio.

There is disclosed a technique listed below.
[Patent Document 1] US Patent Application Publication No. 2023/0369278

For example, Patent Document 1 discloses a semiconductor device in which a source electrode of a power semiconductor chip mounted on a die pad via a die bond material is electrically connected to a lead terminal via a wire.

### SUMMARY

As described above, to detect the load current, the sense transistor for current sense may be provided in the semiconductor chip, and the detection point for detecting the value of the current may be provided to a part of the source electrode of the power transistor provided in the semiconductor chip. However, with a state change of the die bond material, electric characteristics of the semiconductor device may fluctuate.

Other problems and novel features will be apparent from the description of the present specification and the accompanying drawings.

A semiconductor device according to one embodiment includes a die pad, a first semiconductor chip mounted on the die pad, a first lead terminal arranged away from the die pad, a conductive material arranged between the first semiconductor chip and the die pad, and a first bonding member having conductivity. The first semiconductor chip has a sense transistor, a power transistor, and a first source electrode electrically connected to a source region of the power transistor. The first source electrode is electrically connected to the first lead terminal via the first bonding member. The first source electrode includes a detection point for detecting a value of a current flowing in the power transistor and a first bonding portion to which the first bonding member is bonded. In transparent plan view, the die pad has a first region overlapping with the first semiconductor chip and a second region overlapping with the first semiconductor chip and different from the first region. In transparent plan view, the sense transistor, the detection point, and the first bonding portion do not overlap with the first region, but overlap with the second region. In cross-sectional view, a thickness of the conductive material provided in the second region is larger than a thickness of the conductive material provided in the first region.

A method of manufacturing a semiconductor device according to one embodiment includes (a) preparing a die pad having a first region and a second region different from the first region, (b) mounting a first semiconductor chip on the die pad via a conductive material, the first semiconductor chip having a sense transistor, a power transistor, and a first source electrode electrically connected to a source region of the power transistor, and (c) bonding a first bonding member having conductivity to the first source electrode. The first source electrode includes a detection point for detecting a value of a current flowing in the power transistor and a first bonding portion to which the first bonding member is bonded. In the (b), the first semiconductor chip is mounted on the die pad such that the sense transistor, the detection point, and the first bonding portion to which the first bonding member is bonded in the (c) do not overlap with the first region, but overlap with the second region in transparent plan view. After the (b), in cross-sectional view, a thickness of the conductive material provided in the second region is larger than a thickness of the conductive material provided in the first region.

According to one embodiment, reliability of the semiconductor device can be improved.

### BRIEF DESCRIPTION OF THE DRAWINGS

FIG. 1 is an equivalent circuit diagram showing a semiconductor device in one embodiment.

FIG. 2 is a plan view showing an implementation configuration of the semiconductor device in the embodiment.

FIG. 3A is a cross-sectional view taken along line A-A shown in FIG. 2.

FIG. 3B is a cross-sectional view taken along line B-B shown in FIG. 2.

FIG. 4 is a plan view of a main part enlarging one portion of FIG. 2.

FIG. 5 is a plan view of a main part enlarging one portion of FIG. 2.

FIG. 6 is a plan view for describing a configuration of a die pad in the embodiment.

FIG. 7 is a cross-sectional view showing an implementation configuration of a semiconductor device of a consideration example.

FIG. 8 is a cross-sectional view showing a power transistor and a sense transistor according to the embodiment.

FIG. 9 is a cross-sectional view showing a MOSFET in the embodiment.

FIG. 10 is a plan view for describing a position of a detection point in the embodiment.

FIG. 11 is a plan view for describing a configuration of a die pad in the embodiment.

FIG. 12 is a flowchart of a manufacturing method of the semiconductor device in the embodiment.

FIG. 13A is a cross-sectional view showing the manufacturing method of the semiconductor device in the embodiment.

FIG. 13B is a cross-sectional view taken along a line different from that of FIG. 13A.

FIG. 14A is a cross-sectional view showing the manufacturing method of the semiconductor device continued from FIG. 13A and FIG. 13B.

FIG. 14B is a cross-sectional view taken along a line different from that of FIG. 14A.

### DETAILED DESCRIPTION

Hereinafter, embodiments of the present invention will be described in detail with reference to the accompanying drawings. Note that components having the same function are denoted by the same reference characters throughout the drawings for describing the embodiments, and a repetitive description thereof will be omitted. In addition, the description of the same or similar portions is not repeated in principle unless particularly required in the following embodiments.

In this application, the embodiment will be described in a plurality of sections or the like when required as a matter of convenience. However, these sections are not mutually independent or separate unless otherwise stated, and regardless of the order of description, they constitute respective portions of a single example, or one may represent a further detail or modification, in part or in whole, of another. In addition, the repetitive description of the similar parts will be omitted in principle. Further, the components in the embodiments are not always indispensable unless otherwise stated or except for the case where the components are logically limited to that number and the components are apparently indispensable from the context.

In addition, an X direction, a Y direction, and a Z direction described in the present application intersect with one another, and are perpendicular to one another. In the present application, the Z direction is described as an up-down direction, a depth direction, or a thickness direction of a certain structure body. Further, the expression “plan view” or the like used in the present application means that a plane configured by the X direction and the Y direction is defined as “plan” and this “plan” is viewed in the Z direction.

In addition, in the attached drawings, hatching may be omitted even in cross sections in the case where it becomes rather complicated or the case where discrimination from void is clear. In this regard, when it is clear from the description or the like, an outline of a background may be omitted even in a planarly closed hole. Furthermore, even other than the cross section, hatching or dot patterns may be drawn so as to clarify non-voids or clarify a boundary of regions.

### Equivalent Circuit of Semiconductor Device

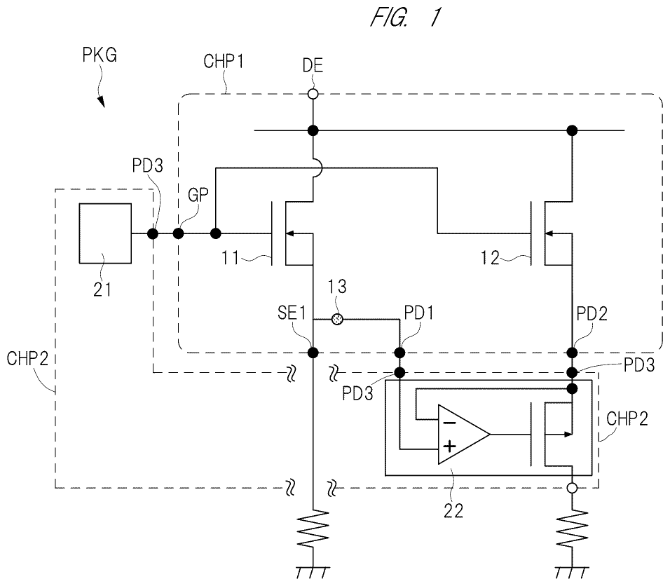

Hereinafter, by using FIG. 1, a semiconductor device PKG according to the present embodiment will be described. The semiconductor device PKG is a semiconductor package including a semiconductor chip CHP1 and a semiconductor chip CHP2.

As shown in FIG. 1, the semiconductor chip CHP1 has a power transistor 11 and a sense transistor 12. The power transistor 11 configures a main cell of the semiconductor chip CHP1. The sense transistor 12 is used in detecting a value of a current flowing in the power transistor 11.

For example, the power transistor 11 and the sense transistor 12 configure a current mirror circuit such that “value of current flowing in power transistor 11: value of current flowing in sense transistor 12=10000:1 (sense ratio)” is satisfied.

In addition, a source electrode SE1 of the power transistor 11 includes a detection point 13 for detecting the value of the current flowing in the power transistor 11.

The semiconductor chip CHP2 has a gate potential control circuit 21 and a sense circuit 22. The gate potential control circuit 21 is electrically connected to each gate electrode of the power transistor 11 and the sense transistor 12. The gate potential control circuit 21 controls a gate potential supplied to the power transistor 11, and controls on/off of the power transistor 11.

The sense circuit 22 is electrically connected to the source electrode SE1 via the detection point 13, and is electrically connected also to a source region of the sense transistor 12. The sense circuit 22 measures the value of the current flowing in the power transistor 11 based on the value of the current flowing in the sense transistor 12 and on the preset sense ratio.

In details, to the sense circuit 22, a source voltage of the sense transistor 12 is inputted from the pad PD2 electrically connected to the sense transistor 12, and a source voltage of the power transistor 11 is inputted from the pad PD1 electrically connected to the source electrode SE1. Then, the sense circuit 22 corrects the source voltage of the sense transistor 12 and the source voltage of the power transistor 11 such that a difference between the both source voltages becomes 0 (zero). In other words, the sense circuit 22 corrects the source voltage of the sense transistor 12 and the source voltage of the power transistor 11 such that the both source voltages are equal to each other. Thereafter, the sense circuit 22 converts a sense current inputted from the pad PD2 into a voltage signal. In this way, based on the voltage signal and the preset sense ratio, the value of the current flowing in the power transistor 11 is measured.

Note that the sense ratio is “value of current flowing in power transistor 11/value of current flowing in sense transistor 12.” The “value of current flowing in sense transistor 12” can calculated by replacing it by “source voltage of power transistor 11 inputted from pad PD1/resistance value of sense transistor 12.”

If an abnormal value such as an overcurrent is detected as the value of the current flowing in the power transistor 11, the gate potential control circuit 21 controls the gate potential supplied to the power transistor 11 and makes the power transistor 11, for example, an off state.

### Implementation Configuration of Semiconductor Device

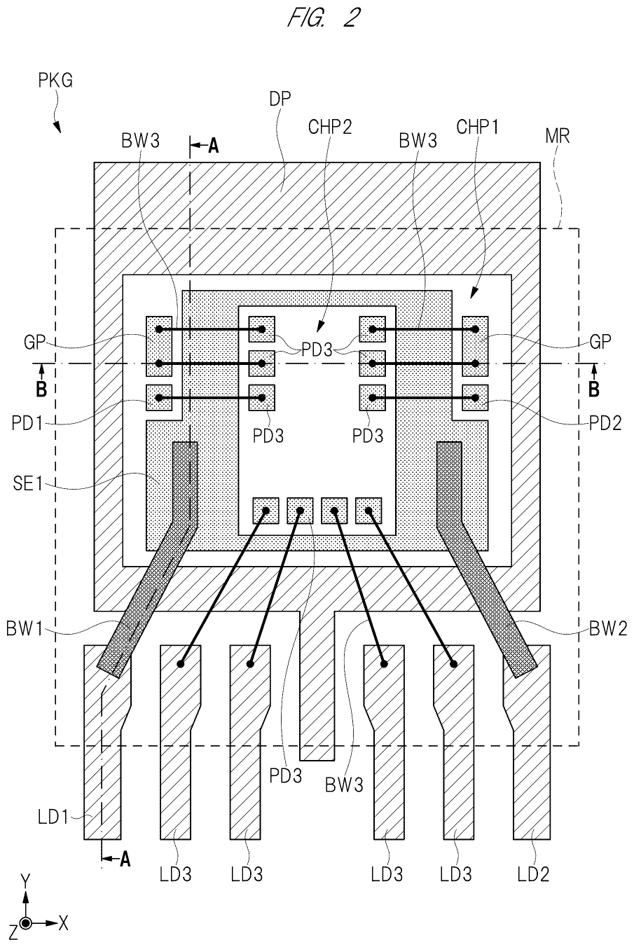

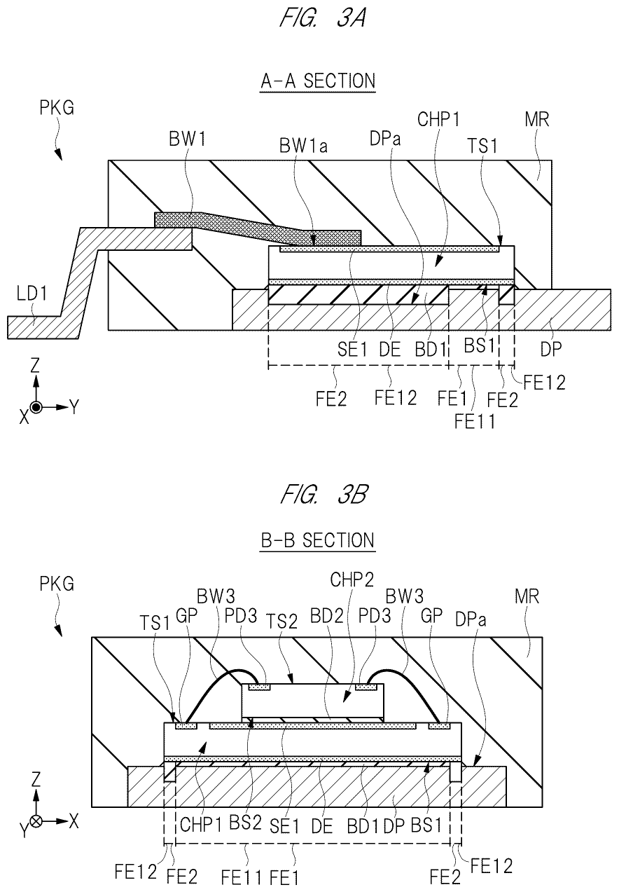

Hereinafter, by using FIG. 2, FIG. 3A, and FIG. 3B, an implementation configuration of the semiconductor device PKG will be described. FIG. 3A is a cross-sectional view taken along line A-A shown in FIG. 2. FIG. 3B is a cross-sectional view taken along line B-B shown in FIG. 2.

As shown in FIG. 2, FIG. 3A, and FIG. 3B, the semiconductor device PKG has the semiconductor chip CHP1, the semiconductor chip CHP2, the die pad DP, a lead terminal LD1, a lead terminal LD2, a plurality of lead terminals LD3, a wire BW1, a wire BW2, a plurality of wires BW3, and a resin sealing body MR.

The die pad DP, the lead terminal LD1, the lead terminal LD2, and the plurality of lead terminals LD3 are arranged away from one another, and are made of, for example, a metal material such as a copper alloy.

The semiconductor chip CHP1 has an upper surface TS1 and a lower surface BS1. In addition, the lower surface BS1 has a region FE11 overlapping with a region FE1 of the die pad DP, and a region FE12 overlapping with a region FE2 of the die pad DP when the semiconductor chip CHP1 is mounted on the die pad DP as shown in FIG. 3A and FIG. 3B. The semiconductor chip CHP1 has the source electrode SE1, a gate pad GP, the pad PD1, and the pad PD2 that are formed on the upper surface TS1. Each of the source electrode SE1 and the pad PD1 is electrically connected to the source region of the power transistor 11. The gate pad GP is electrically connected to each gate electrode of the power transistor 11 and the sense transistor 12. The pad PD2 is electrically connected to the source region of the sense transistor 12.

In addition, the semiconductor chip CHP1 has a drain electrode DE formed on the lower surface BS1. The drain electrode DE is electrically connected to each drain region of the power transistor 11 and the sense transistor 12.

The semiconductor chip CHP1 is mounted on the die pad DP via a conductive bonding material (die bond material) BD1 such that the lower surface BS1 opposes the die pad DP. That is, the drain electrode DE is electrically connected to the die pad DP via the conductive bonding material BD1. The conductive bonding material BD1 is, for example, solder and silver paste. As shown in FIG. 3A and FIG. 3B, in the die pad DP, a trench having a side surface and a bottom surface (corresponding to an upper surface DPa described later) is formed. A detailed structure of the die pad DP will be described later.

The semiconductor chip CHP2 has an upper surface TS2 and a lower surface BS2. The semiconductor chip CHP2 has a plurality of pads PD3 formed on the upper surface TS2. The semiconductor chip CHP2 is mounted on the source electrode SE1 via an insulative bonding material (die bond material) BD2 such that the lower surface BS2 opposes the upper surface TS1 of the semiconductor chip CHP1. The insulative bonding material BD2 is, for example, a Die Attach Film (DAF) material.

The source electrode SE1 is electrically connected to the lead terminal LD1 via a wire BW1 that is a bonding member having conductivity. The source electrode SE1 is electrically connected to the lead terminal LD2 via a wire BW2 that is a bonding member having conductivity. As shown in FIG. 2, the semiconductor chip CHP2 is located between the wire BW1 and the wire BW2. The gate pad GP, the pad PD1, and the pad PD2 are electrically connected to some of the plurality of pads PD3, respectively, via wires BW3 that are bonding members having conductivity. The others of the plurality of pads PD3 are electrically connected to the plurality of lead terminals LD3, respectively, via the wires BW3.

To reduce a resistance component connected to the source electrode SE1, a thicker wire than the wire BW3 is used for each of the wire BW1 and the wire BW2. That is, each diameter of the wire BW1 and the wire BW2 is larger than a diameter of the wire BW3. Each of the wire BW1 and the wire BW2 is made of, for example, aluminum or an aluminum alloy. The wire BW3 is made of, for example, gold.

The semiconductor chip CHP1, the semiconductor chip CHP2, the die pad DP, the lead terminal LD1, the lead terminal LD2, the plurality of lead terminals LD3, the wire BW1, the wire BW2, and the plurality of wires BW3 are sealed by a resin sealing body MR. A part of each of the die pad DP, the lead terminal LD1, the lead terminal LD2, and the plurality of lead terminals LD3 is exposed outside the resin sealing body MR. The resin sealing body MR is made of, for example, a thermosetting resin material such as an epoxy resin.

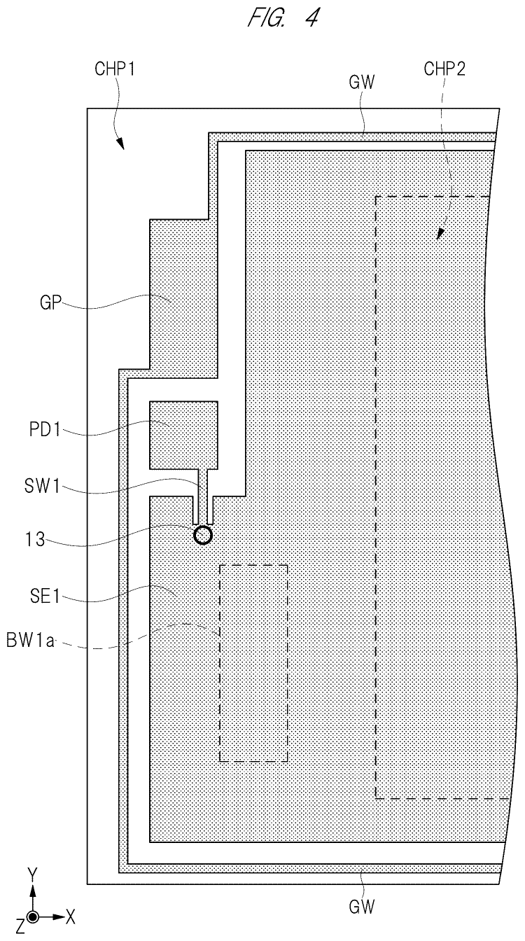

Hereinafter, by using FIG. 4, a detailed structure around the detection point 13 will be described. Note that a bonding portion BW1a shown in FIG. 4 is a portion, to which the wire BW1 is bonded, in the source electrode SE1.

As shown in FIG. 4, the source electrode SE1 includes the detection point 13 for detecting the value of the current flowing in the power transistor 11 in the vicinity of the bonding portion BW1a.

A source wiring SW1 drawn from the detection point 13 is pulled around the source electrode SE1, and is electrically connected to the pad PD1. To ensure a region for arranging the source wiring SW1, a part of the source electrode SE1 has been processed. In other words, a point, to which the source wiring SW1 is connected, in the source electrode SE1 is the detection point 13. Note that, although the source electrode SE1, the source wiring SW1, and the pad PD1 are denoted by different reference characters for convenience here, they are made of the same conductive film and are integrated.

The source electrode SE1 is electrically connected to the sense circuit 22 of the semiconductor chip CHP2 via the detection point 13, the source wiring SW1, the pad PD1, the wire BW3, and the pad PD3.

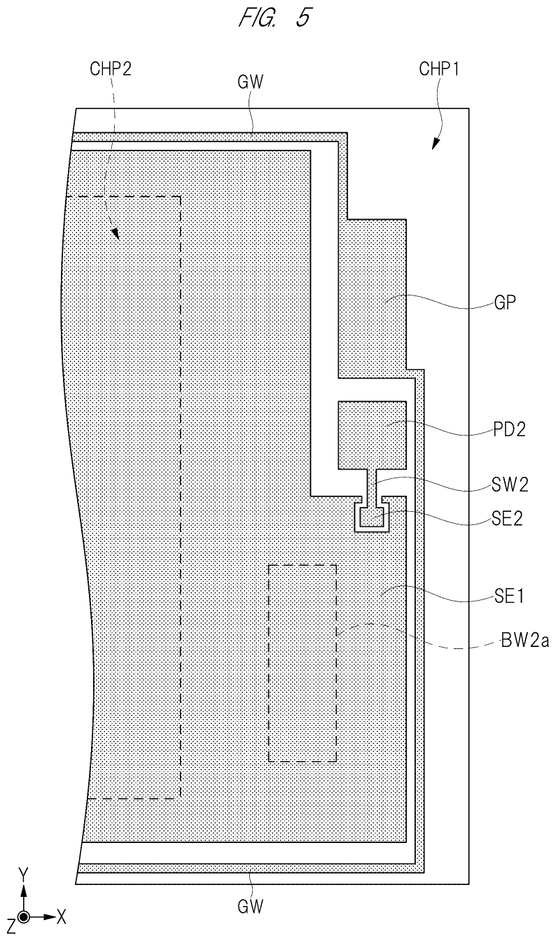

Hereafter, by using FIG. 5, a detailed structure around the sense transistor 12 will be described. Note that a bonding portion BW2a shown in FIG. 5 is a portion, to which the wire BW2 is bonded, in the source electrode SE1.

As shown in FIG. 5, the semiconductor chip CHP1 has a source electrode SE2 formed on the upper surface TS1. The source electrode SE2 is physically separated from the source electrode SE1. The power transistor 11 is formed blow the source electrode SE1. The sense transistor 12 is formed below the source electrode SE2. A source region of the sense transistor 12 is electrically connected to the source electrode SE2.

A source wiring SE2 drawn from the source electrode SE2 is electrically connected to the pad PD2. Note that the source electrode SE2, the source wiring SW2, and the pad PD2 are made of the same conductive film and are integrated.

The source region of the sense transistor 12 is electrically connected to the sense circuit 22 of the semiconductor chip CHP2 via the source electrode SE2, the source wiring SW2, the pad PD2, the wire BW3, and the pad PD3.

In addition, as shown in FIG. 4 and FIG. 5, a gate wiring GW drawn from the gate pad GP is drawn around the source electrode SE1. Although not illustrated in the figure, the gate wiring GW is electrically connected to the gate electrode of each of the power transistor 11 and the sense transistor 12. Note that the gate pad GP and the gate wiring GW are made of the same conductive film and are integrated.

The gate electrode of each of the power transistor 11 and the sense transistor 12 is electrically connected to the gate potential control circuit 21 of the semiconductor chip CHP2 via the gate wiring GW, the gate pad GP, the wire BW3, and the pad PD3.

In addition, the semiconductor chip CHP2 is mounted on the source electrode SE1 so as to be located between the bonding portion BW1a and the bonding portion BW2a.

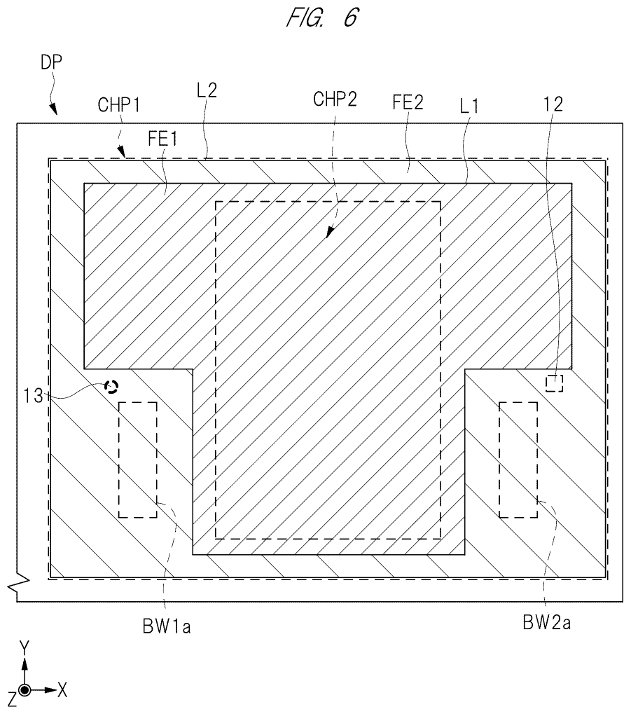

Hereinafter, a structure of the die pad DP will be described by using FIG. 3A, FIG. 3B, and the FIG. 6. As shown in FIG. 6, the die pad DP has a region FE1 and a region FE2 different from the region FE1. The region FE1 is a region surrounded by a solid line L1 in FIG. 6. In addition, when the semiconductor chip CHP1 and the semiconductor chip CHP2 are mounted on the die pad DP, the region FE1 overlaps with each of the semiconductor chip CHP1 and the semiconductor chip CHP2. Meanwhile, the region FE2 is a region obtained by excluding the region surrounded by the solid line L1 from a region surrounded by a sloid line L2 in FIG. 6. That is, as shown in FIG. 6, the region FE1 is surrounded by the region FE2. In addition, when the semiconductor chip CHP1 and the semiconductor chip CHP2 are mounted on the die pad DP, the region FE2 overlaps with the semiconductor chip CHP1, but does not overlap with the semiconductor chip CHP2. Namely, when the semiconductor chip CHP1 and the semiconductor chip CHP2 are mounted on the die pad DP, the region FE2 is a region sandwiched between an outer circumference of the semiconductor chip CHP1 and an outer circumference of the region FE1. After mounting the semiconductor chip CHP1 on the die pad DP, as shown in FIG. 3A and FIG. 3B, a distance between the upper surface DPa (corresponding to a bottom surface of the trench) of the die pad DP in the region FE2 and the lower surface of the semiconductor chip CHP1 in the region FE12 is larger than a distance between the upper surface DPa of the die pad DP in the region FE2 and the lower surface of the semiconductor chip CHP1 in the region FE11. In addition, in FIG. 3A and FIG. 3B, a thickness of the die pad DP in the region FE2 is smaller than a thickness of the die pad DP in the region FE1. A difference between the thickness of the die pad DP in the region FE2 and the thickness of the die pad DP in the region FE1 is, for example, 5 μm or more and 90 μm or less. In the present embodiment, the difference between the thickness of the die pad DP in the region FE2 and the thickness of the die pad DP in the region FE1 is 30 μm or more and 60 μm or less. A different between a thickness of the region FE2 and a thickness of the region FE1 is obtained by subtracting the thickness of the region FE2 from the thickness of the region FE1.

As shown in FIG. 6, the sense transistor 12 does not overlap with the region FE1, but overlaps with the region FE2. That is, in transparent plan view, the sense transistor 12 is arranged in the region FE2. As shown in FIG. 6, the detection point 13 does not overlap with the region FE1, but overlaps with the region FE2. That is, in transparent plan view, the detection point 13 is arranged in the region FE2. As shown in FIG. 6, the bonding portion BW1a does not overlap with the region FE1, but overlaps with the region FE2. That is, in transparent plan view, the bonding portion BW1a is arranged in the region FE2. As shown in FIG. 6, the bonding portion BW2a does not overlap with the region FE1, but overlaps with the region FE2. That is, in transparent plan view, the bonding portion BW2a is arranged in the region FE2.

As shown in FIG. 6, the semiconductor chip CHP2 overlaps with the region FE1. Note that, in the present embodiment, as shown in FIG. 6, the semiconductor chip CHP2 does not overlap with the region FE2. That is, in transparent plan view, the semiconductor chip CHP2 is arranged in the region FE1.

As shown in FIG. 6, the region FE2 is circumferentially provided along an edge of the semiconductor chip CHP1. In addition, in plan view, an area of the region FE1 is larger than an area of the region FE2.

As shown in FIG. 3A and FIG. 3B, a thickness of the conductive bonding material BD1 provided in the region FE2 is larger than a thickness of the conductive bonding material BD1 provided in the region FE1. The conductive bonding material BD1 is formed so as to fill the trench formed in the die pad DP.

The thickness of the conductive bonding material BD1 provided in the region FE1 is, for example, 10 μm or more and 40 μm or less. The thickness of the conductive bonding material BD1 provided in the region FE2 is, for example, 40 μm or more and 100 μm or less. A difference between the thickness of the conductive bonding material BD1 provided in the region FE1 and the thickness of the conductive bonding material BD1 provided in the region FE2 is, for example, 5 μm or more and 90 μm or less. The difference between the thickness of the conductive bonding material BD1 provided in the region FE1 and the thickness of the conductive bonding material BD1 provided in the region FE2 is particularly 30 μm or more and 60 μm or less. The difference between the thickness of the conductive bonding material BD1 provided in the region FE1 and the thickness of the conductive bonding material BD1 provided in the region FE2 is obtained by subtracting the thickness of the conductive bonding material BD1 provided in the region FE1 from the thickness of the conductive bonding material BD1 provided in the region FE2.

Next, effects of the semiconductor device PKG according to the present embodiment will be described. In the semiconductor device PKG having the semiconductor chip CHP1 in which the power transistor 11 is formed, the semiconductor device PKG is mounted with the sense transistor 12 on the semiconductor chip CHP1 in order to detect the current flowing in the power transistor 11.

In such a semiconductor chip PKG, shunt resistance externality provided for detecting the current flowing in the power transistor 11 becomes unnecessary. From this, the semiconductor device PKG including the sense transistor 12 is effective from the viewpoint of achieving a reduction in an implementation area and a reduction in the number of parts.

Here, in a system for controlling a current flowing in a load by the power transistor 11, it is important to detect the current flowing in the power transistor 11 with high accuracy in order to realize high efficiency control. Accordingly, it is desirable that the sense transistor 12 having a function of detecting the current flowing in the power transistor 11 has a high-accuracy current detection function. That is, it is desirable to improve a current sense function in the sense transistor 12.

In addition, as a market demand of the semiconductor device PKG having the power transistor 11, a reduction in on-resistance is required. Therefore, by achieving optimization of the channel region, a drift region NV, and the like of the MOSFET 1Q constituting the power transistor 11 and by forming the MOSFET 1Q into lower resistance, the reduction in the on-resistance of the power transistor 11 is achieved.

However, with the reduction in the resistance of the MOSFET 1Q, the currents flowing in the power transistor 11 and the sense transistor 12 have been affected from manufacturing variations of the semiconductor device and a state change of the die bond material.

Specifically, firstly, when the MOSFET 1Q constituting the power transistor 11 is in the on-state, the current passes the die pad DP, the conductive bonding material (die bond material) BD1, the drain electrode DE, the power transistor 11, and the source electrode SE1. Namely, when the MOSFET 1Q is in the on-state, the current mainly flows in a thickness direction of the semiconductor chip CHP1. Therefore, when cracks occur at the die bond material that is located directly under the detection point 13, the bonding portion BW1a, and the bonding portion BW2a and that is to be a current path, the current flowing in the power transistor 11 also leads to changing. That is, the electric characteristics of the semiconductor device fluctuates. Then, since the detection point 13 is preferably arranged such that a representative value (average value) of a potential outputted from the source of the power transistor 11 is obtained, it is desirable not to be affected by the manufacturing variations of the semiconductor device and the state change of the die bond material. Note that this is similar also to the sense transistor 12 detecting the value of the current flowing in the power transistor 11.

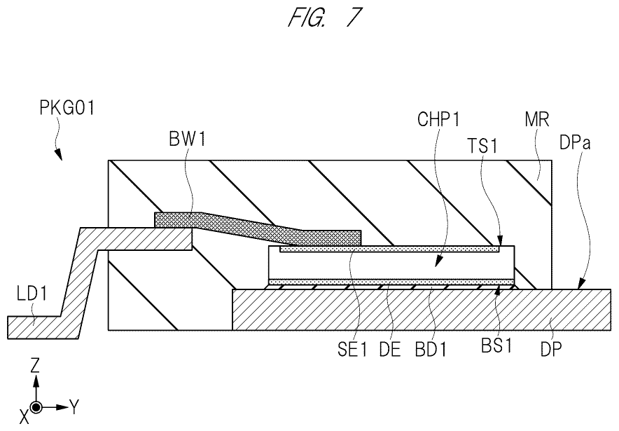

FIG. 7 shows a semiconductor device PKG01 of a consideration example that the inventors of the present application have considered. As understood by comparing FIG. 7 with FIG. 3A and FIG. 3B, in the consideration example, no trench is formed in the die pad DP.

In contrast to this, in the semiconductor device PKG according to the present embodiment, the trench is provided in the region FE2 overlapping with the sense transistor 12, the detection point 13, the bonding portion BW1a, and the bonding portion BW2a. Accordingly, the thickness of the conductive bonding material BD1 located directly under the sense transistor 12, the detection point 13, the bonding portion BW1a, and the bonding portion BW2a can be increased. Note that, as the thickness of the conductive bonding material BD1 is larger, the crucks are difficult to generate. Consequently, it is possible to suppress the crucks generated at the conductive bonding material BD1 located directly under the sense transistor 12, the detection point 13, the bonding portion BW1a, and the bonding portion BW2a due to a thermal history and a temperature difference of the semiconductor device PKG. Then, since the crucks are not generated at the conductive bonding material BD1 located directly under the sense transistor 12, the detection point 13, the bonding portion BW1a, and the bonding portion BW2a, the current detection accuracy of the sense transistor 12 can be improved.

Here, as the thickness of the conductive bonding material BD1 is larger, the crucks are difficult to generate, but the resistance of the conductive bonding material BD1 increases. Therefore, if the entire thickness of the conductive bonding material BD1 increases, the entire resistance of the conductive bonding material BD1 increases. That is, the on-resistance of the power transistor 11 rises. However, in the semiconductor device PKG according to the present embodiment, the thickness of the conductive bonding material BD1 provided in the region FE1 is smaller than the thickness of the conductive bonding material BD1 provided in the region FE2. Namely, the entire thickness of the conductive bonding material BD1 is not made large. Therefore, a rise of the on-resistance of the power transistor 11 can be suppressed. As a result, reliability of the semiconductor device PKG is improved. Nota that the region FE1 in which the thickness of the conductive bonding material BD1 is small does not overlap with the sense transistor 12, the detection point 13, the bonding portion BW1a, and the bonding portion BW2a, so that the current detection accuracy of the sense transistor 12 is less likely to decrease even if the crucks are generated in the region FE1 in which the thickness of the conductive bonding material BD1 is small. Therefore, improving the current detection accuracy and reducing the on-resistance are compatible with each other.

Next, other effects will be described. In the semiconductor device PKG according to the present embodiment, the region FE2 is circumferentially provided along the edge of the semiconductor chip CHP1. Consequently, a thickness of an edge portion of the conductive bonding material BD1 in which the crucks are likely to be generated can be increased. Therefore, the crucks become difficult to generate. As a result, the current detection accuracy of the sense transistor 12 can be further improved.

In addition, in plan view, the area of the region FE1 is larger than the area of the region FE2. Consequently, a region in which the thickness of the conductive bonding material BD1 is small can be increased. Therefore, the on-resistance of the power transistor 11 can be further reduced.

### Sectional Structures of Power Transistor and Sense Transistor

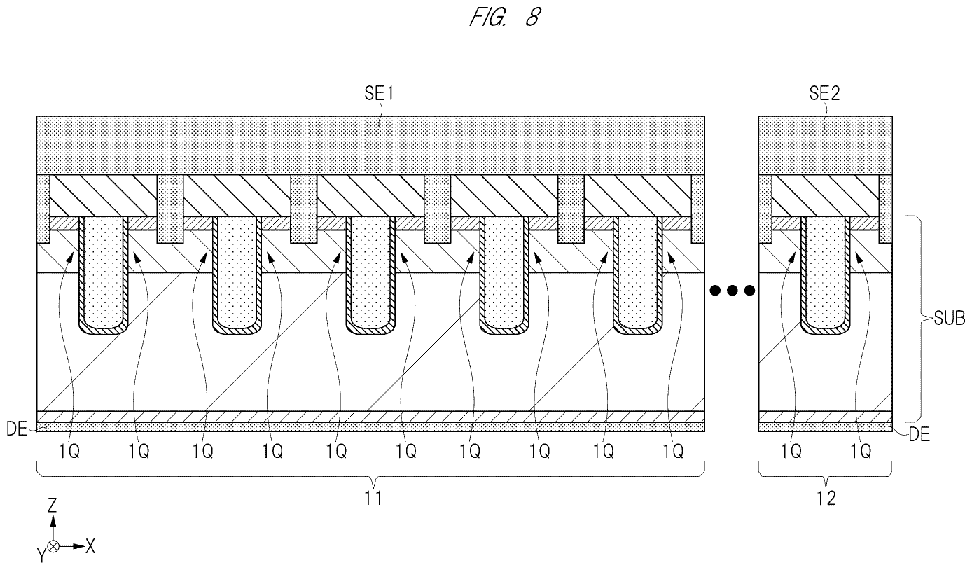

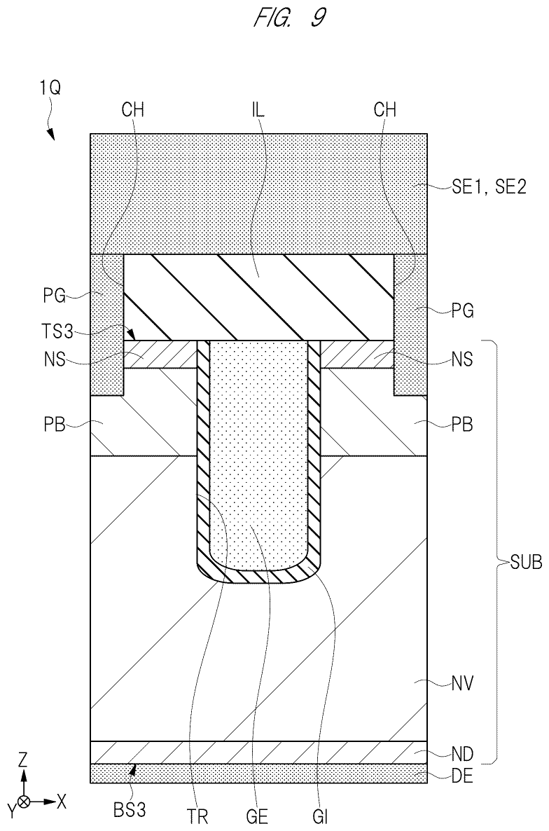

Hereinafter, by using FIG. 8 and FIG. 9, sectional structures of a plurality of Metal Oxide Semiconductor Field Effect Transistors (MOSFETs) constituting the power transistor 11 and the sense transistor 12 will be described.

As shown in FIG. 8, a plurality of n-type MOSFETs 1Q are formed in a semiconductor substrate SUB. The power transistor 11 shown in FIG. 1 is configured by the plurality of MOSFETs 1Q being connected to each other in parallel. The sense transistor 12 shown in FIG. 1 is configured by at least one MOSFET 1Q. The sense transistor 12 may be configured by the plurality of MOSFETs 1Q being connected to each other in parallel. However, at this case, the number of MOSFETs 1Q constituting the sense transistor 12 is fewer than the number of MOSFETs 1Q constituting the power transistor 11.

By a ratio of an area in which the MOSFET 1Q constituting the power transistor 11 is formed and an area in which the MOSFET 1Q constituting the sense transistor 12 is formed, the sense ratio is substantially determined.

Hereinafter, by using FIG. 9, a detailed structure of the MOSFET 1Q will be described.

As shown in FIG. 9, the semiconductor substrate SUB has an upper surface TS3 and a lower surface BS3, and is made of n-type silicon. The semiconductor substrate SUB has the n-type drift region NV and an n-type drain region ND. The drain region ND is formed in the semiconductor substrate SUB so as to have a predetermined thickness toward the upper surface TS3 of the semiconductor substrate SUB from the lower surface BS3 of the semiconductor substrate SUB. The drain region ND has an impurity concentration higher than that of the drift region NV.

The semiconductor substrate SUB may be a monocrystalline n-type silicon substrate, or may be a lamination body of the n-type silicon substrate and an n-type semiconductor layer grown while introducing phosphorus (P) onto the above n-type silicon substrate by an epitaxial growth method.

Under the lower surface BS3 of the semiconductor substrate SUB, the drain electrode DE is formed. The drain electrode DE is made of, for example, a single-layer metal film such as an aluminum film, a titanium film, a nickel film, a gold film, or a silver film, or a lamination film obtained by laminating these metal films appropriately. The drain region ND and the drain electrode DE are formed on the entire lower surface BS3 of the semiconductor substrate SUB. To the semiconductor substrate SUB (drain region ND, drift region NV), the drain potential is supplied from the drain electrode DE.

In the semiconductor substrate SUB, a trench TR reaching a predetermined depth from the upper surface TS3 of the semiconductor substrate SUB is formed. In the trench TR, the gate electrode GE is formed via a gate insulation film GI. The gate insulation film GI is made of, for example, a silicon oxide film. The gate electrode GE is made of, for example, a polycrystalline silicon film into which n-type impurities are introduced.

In the semiconductor substrate SUB, a p-type body region PB reaching a predetermined depth from the upper surface TS3 of the semiconductor substrate SUB is formed. A depth of the body region PB from the upper surface TS3 of the semiconductor substrate SUB is shallower than a depth of the trench TR from the upper surface TS3 of the semiconductor substrate SUB. In the body region PB, an n-type source region NS is formed. The source region NS has a higher impurity concentration than that of the drift region NV. A portion of the body region PB, which is adjacent to the gate electrode GE via the gate insulation film GI and is located between the source region NS and the drift region NV, constitutes a channel region of the MOSFET 1Q.

An interlayer insulation film IL is formed on the upper surface TS3 of the semiconductor substrate SUB so as to cover the trench TR. The interlayer insulation film IL is made of, for example, a silicon oxide film.

In the interlayer insulation film IL, a hole CH is formed. The hole CH penetrates through the interlayer insulation film IL and the source region NS, and reaches the body region PB. Although not illustrated here, the hole CH reaching the gate electrode GE is also formed in the interlayer insulation film IL. In the hole CH, a plug PG is embedded. The plug PG is made of, for example, a first barrier metal film and a first conductive film formed on the first barrier metal film. The first barrier metal film is made of, for example, a lamination film of a titanium film and a titanium nitride film. The first conductive film is, for example, a tungsten film.

On the interlayer insulation film IL, the source electrode SE1 is formed. The source electrode SE1 is electrically connected to the source region NS and the body region PB via the plug PG, and supplies a source potential to these impurity regions. Note that the source electrode SE2 is formed above the MOSFET 1Q constituting the sense transistor 12.

Although not illustrated here, the gate pad GP, the gate wiring GW, the pad PD1, the source wiring SW1, a pad PD2, and a source wiring SW2 that are shown in FIG. 4 and FIG. 5 are also formed on the interlayer insulation film IL. The gate pad GP is electrically connected to the gate electrode GE via the gate wiring GW and the plug PG, and supplies the gate potential to the gate electrode GE.

The source electrode SE1, the source electrode SE2, the gate pad GP, the gate wiring GW, the pad PD1, the source wiring SW1, the pad PD2, and the source wiring SW2 are made of, for example, a second barrier metal film and a second conductive film formed on the second barrier metal film. The second barrier metal film is, for example, a titanium tungsten film. The second conductive film is, for example, an aluminum alloy film to which copper or silicon is added.

### Modification

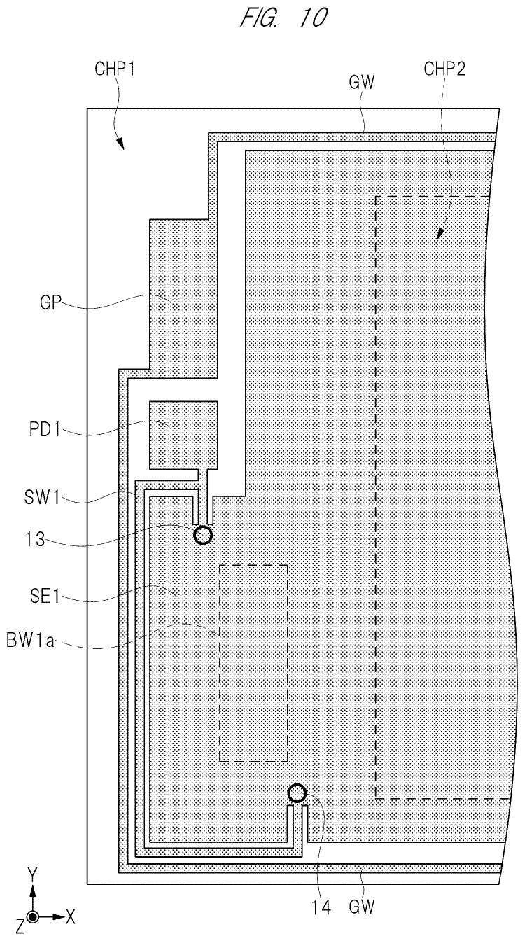

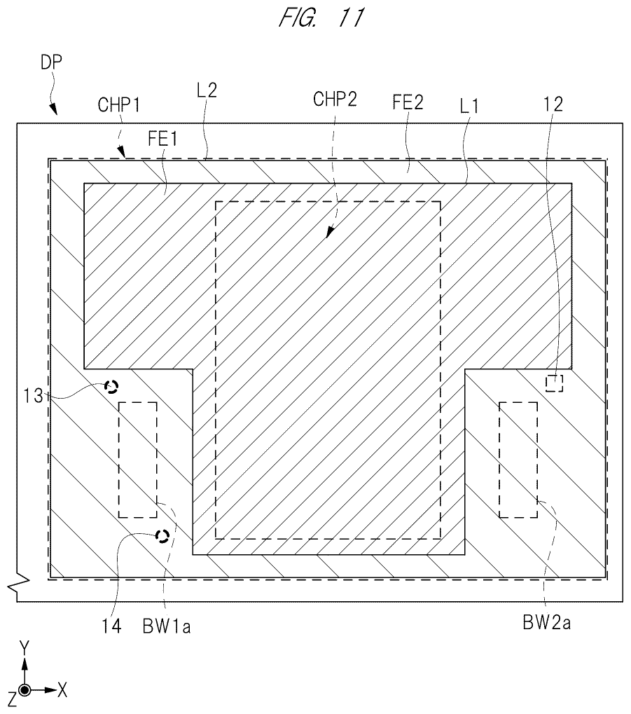

Next, a modification of the semiconductor device according to the present embodiment will be described. FIG. 10 is a plan view of a main part showing the semiconductor device. FIG. 11 is a plan view for describing a configuration of a die pad in the embodiment. The semiconductor device PKG shown in FIG. 10 is different from the semiconductor device shown in FIG. 4 in that it further has a detection point 14. Note that the bonding portion BW1a shown in FIG. 10 is a portion, to which the wire BW1 is bonded, in the source electrode SE1.

As shown in FIG. 10, the source electrode SE1 includes the detection point 13 and the detection point 14 for detecting the value of the current flowing in the power transistor 11 in the vicinity of the bonding portion BW1a. The detection point 13 and the detection point 14 are arranged so as to sandwich the bonding portion BW1a.

The source wiring SW1 drawn from the detection point 13 and the detection point 14 is drawn around the source electrode SE1, and is electrically connected to the pad PD1. To ensure a region for arranging the source wiring SW1, a part of the source electrode SE1 has been processed. In other words, points of the source electrode SE1, to which the source wiring SW1 is connected, are the detection point 13 and the detection point 14. Note that, although the source electrode SE1, the source wiring SW1, and the pad PD1 are denoted by different reference characters for convenience here, they are made of the same conductive film and are integrated.

The source electrode SE1 is electrically connected to a sense circuit 22 of the semiconductor chip CHP2 via the detection point 13, the detection point 14, the source wiring SW1, the pad PD1, the wire BW3, and the pad PD3. As shown in FIG. 11, the detection point 14 does not overlap with the region FE1, but overlaps with the region FE2. That is, in transparent plan view, the detection point 14 is arranged in the region FE2.

According to the semiconductor device PKG shown in FIG. 10, the detection point 13 and the detection point 14 are arranged so as to sandwich the bonding portion BW1a. Therefore, even when assembly variations of the bonding portion BW1a occur, voltages detected at two points of the detection point 13 and the detection point 14 can be averaged. Consequently, a fluctuation of a change rate of the sense ratio can be suppressed. As a result, the current detection accuracy of the sense transistor can be further improved.

### Manufacturing Method of Semiconductor Device

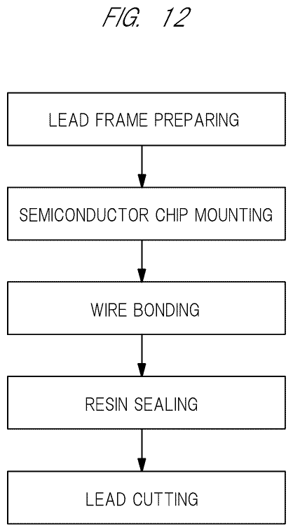

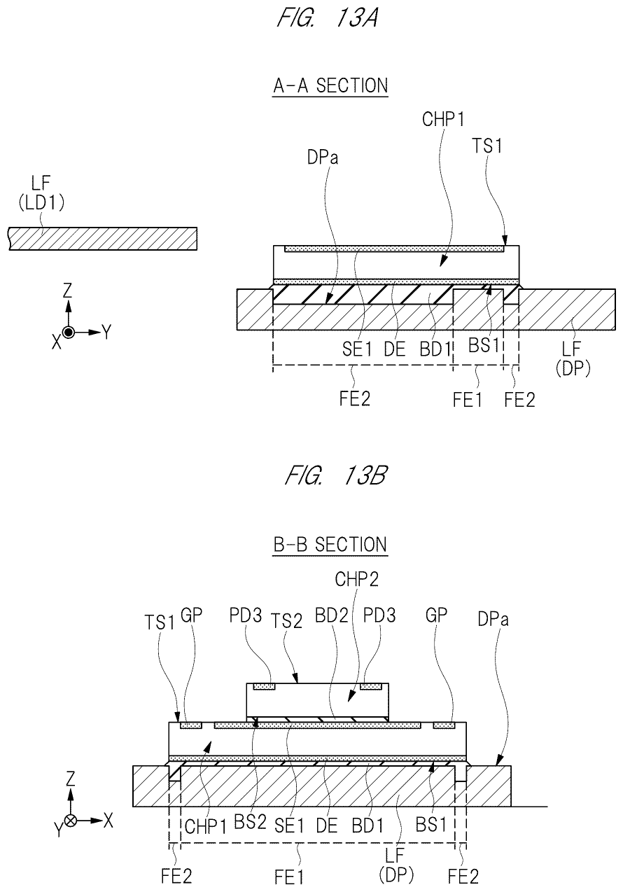

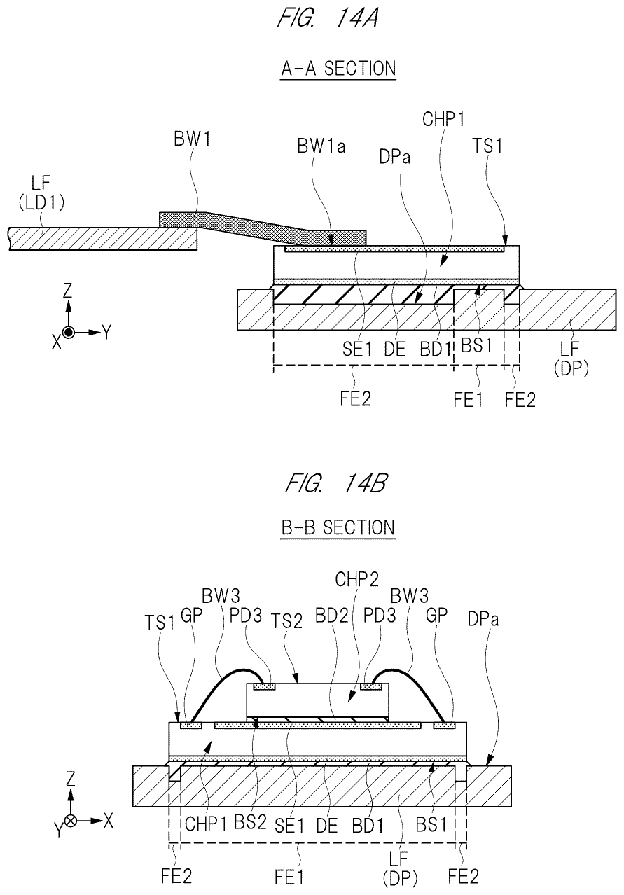

Hereinafter, by using FIG. 12, FIG. 13A, FIG. 13B, FIG. 14A, and FIG. 14B, each manufacturing step included in a manufacturing method of the semiconductor device PKG will be described.

As shown in FIG. 12, FIG. 13A, and FIG. 13B, firstly, the semiconductor chip CHP1, the semiconductor chip CHP2, and a lead frame LF are prepared. The lead frame LF includes a lead terminal LD1, a lead terminal LD2, a lead terminal LD3, and the die pad DP.

As shown in FIG. 13A and FIG. 13B, a trench is provided in the region FE2 of the die pad DP. A thickness of the die pad DP in the region FE1 is larger than a thickness of the die pad DP in the region FE2. In a lead frame preparing step, the die pad DP in which the trench is formed in advance may be used. In addition, in the lead frame preparing step, the die pad DP in which no trench is formed is prepared, and the trench may be formed in the die pad DP.

Next, the semiconductor chip CHP1 is mounted on the upper surface DPa of the die pad DP via the conductive bonding material BD1 such that the lower surface BS1 of the semiconductor chip CHP1 opposes the upper surface DPa of the die pad DP. The semiconductor chip CHP1 can use the semiconductor chip CHP1 of the semiconductor device PKG according to the present embodiment. Namely, the semiconductor chip CHP1 has the power transistor 11, the sense transistor 12, and the source electrode SE1 electrically connected to the source region NS of the power transistor 11. In addition, the source electrode SE1 includes the detection point 13 for detecting the value of the current flowing in the power transistor 11, and the bonding portion BW1a and the boding portion BW2a to which the wire BW1 and the wire BW2 are respectively bonded in a wire bonding step described later.

As shown in FIG. 6, in a step of mounting the semiconductor chip CHP1, the semiconductor chip CHP1 is mounted on the die pad DP such that the sense transistor 12, the detection point 13, the bonding portion BW1a, and the bonding portion BW2a do not overlap with the region FE1, but overlap with the region FE2 in transparent plan view.

As shown in FIG. 3A and FIG. 3B, a thickness of the conductive bonding material (conductive member) BD1 provided in the region FE2 is larger than a thickness of the conductive bonding material BD1 provided in the region FE1.

Next, the semiconductor chip CHP2 is mounted on the source electrode SE1 via an insulative bonding material BD2 such that the lower surface BS2 of the semiconductor chip CHP2 opposes the upper surface TS1 of the semiconductor chip CHP1.

Next, as shown in FIG. 14A and FIG. 14B, the wire bonding is carried out. By the wire BW1, the source electrode SE1 and the lead terminal LD1 are electrically connected. By the wire BW3, the pad PD3 electrically connected to the gate potential control circuit 21 and the gate pad GP are electrically connected. Although not illustrated here, the source electrode SE1 and the lead terminal LD2 are electrically connected by the wire BW2. By the wire BW3, the pad PD3 electrically connected to the gate potential control circuit 21 and the gate pad GP connected to the gate of the power transistor 11 are electrically connected to each other. By the wire BW3, the pad PD3 electrically connected to the sense circuit 22 and the pad PD2 electrically connected to the sense transistor 12 are electrically connected. By the plurality of wires BW3, the plurality of other pads PD3 and the plurality of lead terminals LD3 are electrically connected.

In addition, in the present wire bonding step, a part (bonding part) of the wire BW1 is bonded to a portion of the source electrode SE1, which does not overlap with the region FE1, but overlaps with the region FE2 (the bonding portion BW1a and the bonding portion BW2a described in FIG. 6).

Then, by performing the manufacturing steps described below, the semiconductor device PKG shown in FIG. 2, FIG. 3A, and FIG. 3B is manufactured. Firstly, the semiconductor chip CHP1, the semiconductor chip CHP2, the die pad DP, the lead terminal LD1, the lead terminal LD2, the plurality of lead terminals LD3, the wire BW1, the wire BW2, and the plurality of wires BW3 are sealed by a resin, thereby forming the resin sealing body MR. Note that a part of each of the die pad DP, the lead terminal LD1, the lead terminal LD2, the plurality of lead terminals LD3 is exposed outside the resin sealing body MR.

Next, the die pad DP, the lead terminal LD1, the lead terminal LD2, and the lead terminals LD3 are cut and taken out from the lead frame LF. Next, the lead terminal LD1, the lead terminal LD2, and the lead terminals LD3 are bent. From the above, the semiconductor device PKG can be manufactured.

In the foregoing, the present invention has been specifically described based on the above embodiments, but the present invention is not limited to the above embodiments and can be variously modified within a range not departing from the gist thereof.

For example, in the above embodiments, use of the wires BW1, BW2, BW3 as the bonding members having conductivity to be bonded to the lead terminals LD1, LD2, LD3 has been described. However, if there is a clip in which a width (area) of a portion bonded to the source electrode SE1 or the pad PD3 is small, the clip may be used as the bonding members having conductivity to be bonded to the lead terminals LD1 and LD2.

What is claimed is:

1. A semiconductor device comprising:
a die pad;
a first semiconductor chip mounted on the die pad;
a first lead terminal arranged away from the die pad;
a conductive material arranged between the first semiconductor chip and the die pad; and
a first bonding member having conductivity,
wherein the first semiconductor chip has a sense transistor, a power transistor, and a first source electrode electrically connected to a source region of the power transistor,
wherein the first source electrode is electrically connected to the first lead terminal via the first bonding member,
wherein the first source electrode includes:
a detection point for detecting a value of a current flowing in the power transistor; and
a first bonding portion to which the first bonding member is bonded,
wherein, in transparent plan view, the die pad has:
a first region overlapping with the first semiconductor chip; and
a second region overlapping with the first semiconductor chip and different from the first region,
wherein, in transparent plan view, the sense transistor, the detection point, and the first bonding portion do not overlap with the first region, but overlap with the second region, and
wherein, in cross-sectional view, a thickness of the conductive material provided in the second region is larger than a thickness of the conductive material provided in the first region.

2. The semiconductor device according to claim 1,
wherein, in cross-sectional view, a distance between an upper surface of the die pad in the second region and a lower surface of the first semiconductor chip in a fourth region is larger than a distance between the upper surface of the die pad in the first region and the lower surface of the first semiconductor chip in a third region.

3. The semiconductor device according to claim 1,
wherein, in plan view, an area of the first region is larger than an area of the second region.

4. The semiconductor device according to claim 1,
wherein, in transparent plan view, the second region is circumferentially arranged along an edge of the first semiconductor chip.

5. The semiconductor device according to claim 1, further comprising a second semiconductor chip, a second lead terminal arranged away from the die pad and the first lead terminal, and a second bonding member having conductivity,
wherein the first source electrode is electrically connected to the second lead terminal via the second bonding member having conductivity,
wherein the second semiconductor chip is mounted on the first source electrode so as to be located between a second bonding portion to which the second bonding member having conductivity is bonded to the first source electrode and the first bonding portion, and
wherein, in transparent plan view, the second semiconductor chip overlaps with the first region.

6. The semiconductor device according to claim 5,
wherein the first semiconductor chip further has a source wiring drawn from the detection point and a first pad electrically connected to the source wiring.

7. The semiconductor device according to claim 6,
wherein the first semiconductor chip further has a second pad electrically connected to a source region of the sense transistor,
wherein the second semiconductor chip further has a sense circuit for measuring a value of a current flowing in the power transistor based on a value of a current flowing in the sense transistor and on a preset sense ratio, a third pad electrically connected to the sense circuit, and a fourth pad electrically connected to the sense circuit,
wherein the first pad is electrically connected to the third pad via a third bonding member having conductivity, and
wherein the second pad is electrically connected to the fourth pad via a fourth bonding member having conductivity.

8. The semiconductor device according to claim 7,
wherein a diameter of each of the first bonding member having conductivity and the second bonding member having conductivity is larger than a diameter of each of the third bonding member having conductivity and the fourth bonding member having conductivity.

9. The semiconductor device according to claim 2,
wherein a difference between a thickness of the conductive material arranged in the first region and a thickness of the conductive material arranged in the second region is 5 μm or more and 90 μm or less.

10. A method of manufacturing a semiconductor device, the method comprising:
(a) preparing a die pad having a first region and a second region different from the first region;
(b) mounting a first semiconductor chip on the die pad via a conductive material, the first semiconductor chip having a sense transistor, a power transistor, and a first source electrode electrically connected to a source region of the power transistor; and
(c) bonding a first bonding member having conductivity to the first source electrode,
wherein the first source electrode includes:
a detection point for detecting a value of a current flowing in the power transistor; and
a first bonding portion to which the first bonding member is bonded,
wherein, in the (b), the first semiconductor chip is mounted on the die pad such that the sense transistor, the detection point, and the first bonding portion to which the first bonding member is bonded in the (c) do not overlap with the first region, but overlap with the second region in transparent plan view, and
wherein, after the (b), in cross-sectional view, a thickness of the conductive material provided in the second region is larger than a thickness of the conductive material provided in the first region.
